(19) United States
(12) Patent Application Publication
(10) Pub. No.: US 2025/0169037 A1
(43) Pub. Date: May 22, 2025

(54) DETECTING MECHANISM

(71) Applicant: Shenzhen Envicool Technology Co., Ltd., Shenzhen (CN)

(72) Inventors: Chengsheng SONG, Shenzhen (CN); Xianwen REN, Shenzhen (CN)

(73) Assignee: Shenzhen Envicool Technology Co., Ltd., Shenzhen (CN)

(21) Appl. No.: 19/031,125

(22) Filed: Jan. 17, 2025

Related U.S. Application Data
(63) Continuation of application No. PCT/CN2024/128927, filed on Oct. 31, 2024.

(30) Foreign Application Priority Data
Nov. 1, 2023 (CN) 202311445223.4

(51) Int. Cl. H05K 7/20; G01M 3/02

(52) U.S. Cl. CPC H05K 7/20272; H05K 7/20254; G01M 3/02

(57) ABSTRACT

The present invention discloses a detecting mechanism, the detecting mechanism comprising: a housing and a leak-proof conduit; wherein the housing is used to cover a liquid cooling plate of a liquid cooling device to be detected; the leak-proof conduit is used to be fitted over a coolant conduit of the liquid cooling device to be detected, and either or each of the housing and the leak-proof conduit is provided with a leakage detection sensor. When the coolant conduit leaks, the coolant will flow into the leak-proof conduit. By setting a housing on the liquid cooling plate, when the liquid cooling plate leaks, the coolant will be temporarily stored in the protective chamber. By setting the housing and leak-proof conduit, the leaked coolant can be temporarily stored, preventing the leaked coolant from dripping onto the working components and causing damage to the working components.

### CROSS-REFERENCE

The present invention claims priority to a Chinese Patent Application No. 202311445223.4, filed on Nov. 1, 2023, titled “Detecting Mechanism”, the entire contents of which are incorporated herein by reference.

### FIELD

The present invention relates to the technical field of electronic devices, and in particular relates to a detecting mechanism.

### BACKGROUND

At present, as the performance of electronic devices continues to improve, the heat generated by the working components inside the electronic devices also increases. In order to cool the working components, a liquid cooling device is generally attached to the outside of the working components, and the low-temperature liquid inside the liquid cooling device carries away the heat from the working components to cool the working components.

Typically, a liquid cooling device includes a liquid cooling plate and a coolant conduit. The liquid cooling plate is provided with a flow channel for the coolant to flow. The coolant conduit is set up with two lines, both of which are connected to the coolant flow channel in the liquid cooling plate. One of the two coolant conduits serves as an inlet pipe and the other as an outlet pipe, so that the coolant circulates in the coolant flow channel.

However, when the liquid cooling device is working, due to problems such as poor sealing, there may be coolant leakage. The leaked coolant droplets falling on the working components may cause damage to the working components. Currently, in order to solve the above problems, some manufacturers will wrap a leak detection line around the liquid pipe to form a liquid cooling device, which is used to detect the leakage of coolant. However, such a liquid cooling device can only detect the leakage of coolant in a certain direction and/or a certain section of the pipe, that is, when the coolant leaks in the area where the leak detection line is not wrapped, the leaked coolant may not flow to the leak detection line, resulting in low accuracy in detecting coolant leakage.

### SUMMARY

To solve the aforementioned problems of the prior art, the present invention provides a detecting mechanism to address the low accuracy of detecting coolant leakage.

To address the technical problems mentioned above, the present application provides a detecting mechanism, comprising: a housing and a leak-proof conduit; wherein the housing is used to cover a liquid cooling plate of a liquid cooling device to be detected; the leak-proof conduit is used to be fitted over a coolant conduit of the liquid cooling device to be detected, and either or each of the housing and the leak-proof conduit is provided with a leakage detection sensor.

In some embodiments, a first gap is defined between the leak-proof conduit and the coolant conduit, and the housing communicates with the exteriority through the first gap.

In some embodiments, a protective chamber is defined between the housing and the liquid cooling plate, the protective chamber communicates with the exteriority through the first gap; the liquid cooling plate is provided with an interface communicating the exteriority with the liquid cooling plate, the interface is located in the protective chamber, and the coolant conduit is connected to the interface.

In some embodiments, a side wall of the housing is provided with a through-hole; the coolant conduit passes through the through-hole, extends into the housing and communicates with the liquid cooling plate; a second gap is defined between the coolant conduit and the through-hole; the leak-proof conduit is connected to the external surface of the through-hole, and the first gap communicates with the housing through the second gap.

In some embodiments, an outer wall of the housing is provided with a connecting portion, the connecting portion is disposed corresponding to the through-hole, the connecting portion is provided with a passage communicating with the through-hole; the leak-proof conduit is connected to the connecting portion, the coolant conduit passes through the passage and the through-hole to extend into the housing; a second gap is defined between the coolant conduit and the through-hole, and the first gap communicates with the housing through the second gap.

In some embodiments, the connecting portion is a cylindrical joint, and the cylindrical joint is inserted into the leak-proof conduit.

In some embodiments, the leak-proof conduit and the connecting portion are sealed therebetween.

In some embodiments, the housing comprises a frame and a cover; one end of the frame is connected to the cover plate, and the other end is connected to the liquid cooling plate; and the liquid cooling plate, the frame, and the cover plate jointly enclose the protective chamber, when the housing is fitted onto the liquid cooling plate.

In some embodiments, the frame and the cover plate are sealed therebetween, and the frame and the liquid cooling plate are sealed therebetween.

In some embodiments, the detecting mechanism comprises a recycling component, wherein the recycling component is used for recycling the coolant; the leak-proof conduit communicates with a diversion conduit at an end away from the housing, and the first gap communicates with the recycling component through the diversion conduit.

To address the technical problems mentioned above, the present application provides a detecting mechanism, comprising: a housing and a leak-proof conduit; the housing is used to cover a liquid cooling plate of a liquid cooling device to be detected; the leak-proof conduit is used to cover a coolant conduit of the liquid cooling device to be detected; wherein a first leakage detection sensor is provided the housing, and a second leakage detection sensor is provided in the leak-proof conduit.

In some embodiments, the housing and the liquid cooling plate enclose a sealed protective chamber, the leak-proof conduit and the coolant conduit defines a first gap, and the protective chamber communicates with the exteriority through the first gap.

In some embodiments, a side wall of the housing defines a through-hole for the coolant conduit to extend into the housing, a second gap is defined between the through-hole and the coolant conduit; the leak-proof conduit is connected to an external surface of the through-hole, and the first gap communicates with the protective chamber through the second gap.

In some embodiments, an inner diameter of the through-hole is larger than an outer diameter of the coolant conduit, and the internal surface of the leak-proof conduit is connected to the external surface of the through-hole.

In some embodiments, a connecting portion is provided at the through-hole, the connecting portion is provided with a passage communicating with the through-hole, and the connecting portion is connected to the leak-proof conduit.

In some embodiments, the leak-proof conduit is a flexible tube, and the leak-proof conduit is provided with a sealing structure at a connection with the connecting portion;
or, the leak-proof conduit is a heat shrink tube, and the connecting portion is inserted into the leak-proof conduit and connected to the leak-proof conduit by heating.

In some embodiments, the housing is a groove-shaped structure and an end with an opening is connected to a top plate of the liquid cooling plate, the housing includes a frame and a cover plate;
the frame and cover plate are integrated, a sealing structure is provided between the frame and the top plate of the liquid cooling plate, and the frame is connected to the top plate by bolts; or, the frame and the cover plate are separate structures, a sealing structure is provided between the frame and the cover plate, a sealing structure is provided between the frame and the top plate, the frame and the cover plate are connected by bolts, and the frame and the top plate are connected by bolts.

In some embodiments, the leak-proof conduit branches off at an end away from the housing to form a diversion conduit, and the first gap communicates with the recycling component through the diversion conduit.

In some embodiments, the protective chamber receives an interface on the liquid cooling plate connected to a coolant conduit.

In some embodiments, one end of the leak-proof conduit away from the housing is lower than the other end of the leak-proof conduit closer to the housing.

The detecting mechanism provided in the above embodiments of the present invention has at least the following beneficial effects:

The application provides a detecting mechanism, comprising a housing and a leak-proof conduit; the housing is used to cover the liquid cooling plate of the liquid cooling device to be detected; the leak-proof conduit is used to cover the outside of the coolant conduit of the liquid cooling device to be detected, wherein the housing and/or the leak-proof conduit are provided with a leakage detection sensor.

During the use of a liquid cooling device, if there is a coolant flow in the coolant conduit and the liquid cooling plate, a leak-proof conduit is installed around the coolant conduit. When the coolant conduit leaks, the coolant will flow into the leak-proof conduit. By setting a housing on the liquid cooling plate, when the liquid cooling plate leaks, the coolant will be temporarily stored in the protective chamber. By setting the housing and leak-proof conduit, the leaked coolant can be temporarily stored, avoiding the leaked coolant from dripping onto working components and causing damage to the working components.

Furthermore, a leakage detection sensor is installed within the housing and/or the leak-proof conduit to detect any leakage of coolant. When the liquid cooling plate experiences coolant leakage, the leakage will be temporarily contained within the housing, preventing it from spreading. This allows the leakage detection sensor within the housing to detect the coolant leakage promptly. Similarly, when the coolant conduit experiences coolant leakage, the leakage will be temporarily contained within the leak-proof conduit, preventing it from spreading. This allows the leakage detection sensor within the leak-proof conduit to detect the coolant leakage promptly. Compared to the prior art, the detecting mechanism of the present invention ensures that any coolant leakage will be detected by the leakage detection sensor, resulting in more accurate detection results.

### BRIEF DESCRIPTION OF THE DRAWINGS

The accompanying drawings, which form part of this application, are used to provide a further understanding of the present invention, and the schematic embodiments of the invention and their description are used to explain the invention and do not constitute an undue limitation of the invention. In the accompanying drawings:

FIG. 1 is a schematic structural diagram of a liquid cooling plate according to an embodiment of the invention;

FIG. 2 is a schematic structural diagram of a detecting mechanism according to an embodiment of the invention;

FIG. 3 is a schematic structural diagram of a housing according to the embodiment;

FIG. 4 is a schematic structural diagram of the detecting mechanism assembled to the liquid cooling plate;

FIG. 5 is a schematic sectional view of the detecting mechanism assembled to the liquid cooling plate;

FIG. 6 is a plan view of the detecting mechanism assembled to the liquid cooling plate; and

FIG. 7 is a block diagram of the detecting mechanism according to the embodiment of the invention.

The accompanying drawings are labelled to illustrate:

1, a liquid cooling plate; 12, an interface; 13, a coolant conduit; 21, a housing; 210, a through-hole; 211, a frame; 212, a cover plate; 213, connecting portion; 214, a passage; 22, a leak-proof conduit; 23, a protective chamber; 24, a first gap; 25, a second gap; 26, a diversion conduit; 27, leakage detection sensor.

### DESCRIPTION OF THE EMBODIMENTS

Embodiments of the present invention are described in detail below in conjunction with the accompanying drawings, but the present invention may be practiced in a number of different ways as defined and covered by the claims.

In addition, unless otherwise defined, technical or scientific terms used in the description of the present application shall have the ordinary meaning as understood by a person of ordinary skill in the art to which the present application belongs. As used in the description of the present application, “top”, “bottom”, “left”, “right”, “center,” ‘vertical,’ ‘horizontal,’ ‘inside,’ ‘outside,’ and the like used in this application description to indicate orientation. Words such as “orientation” are only used to indicate relative directions or positional relationships, and do not imply that the device or component must have a specific orientation, be constructed and operated in a specific orientation, and when the absolute position of the described object is changed, its relative positional relationship may also be changed accordingly, and therefore cannot be construed as a limitation of the present application. The terms “first”, “second”, “third” and the like used in the description of the present application are used only for descriptive purposes to distinguish between different components, and cannot be construed as indicating or implying relative importance. They are not to be construed as indicating or implying relative importance. The terms “one”, “a”, “the”, and the like, as used in the description of the present application, should not be construed as an absolute limitation on the number, but rather as the existence of at least one. Words such as “including” or “comprising” as used in the description of the present application are intended to mean that the component or object preceded by the word covers the components or objects listed after the word, and their equivalents, and does not exclude other components or objects.

It should also be noted that, unless otherwise expressly provided and limited, the words “mounted”, “connected”, “linked” and the like as used in the description of the present application are to be understood in a broad sense. For example, the connection may be a fixed connection, a removable connection, or a one-piece connection; it may be a mechanical connection or an electrical connection; it may be a direct connection, an indirect connection through an intermediate medium, or a connection within two elements, and the person skilled in the art may understand the specific meaning in the present application according to the specific circumstances.

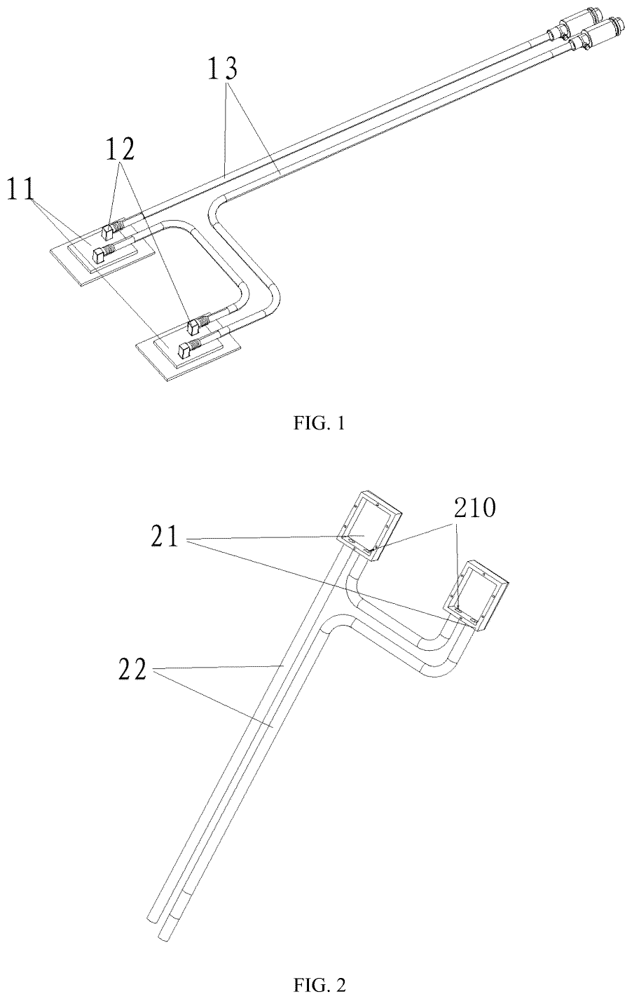

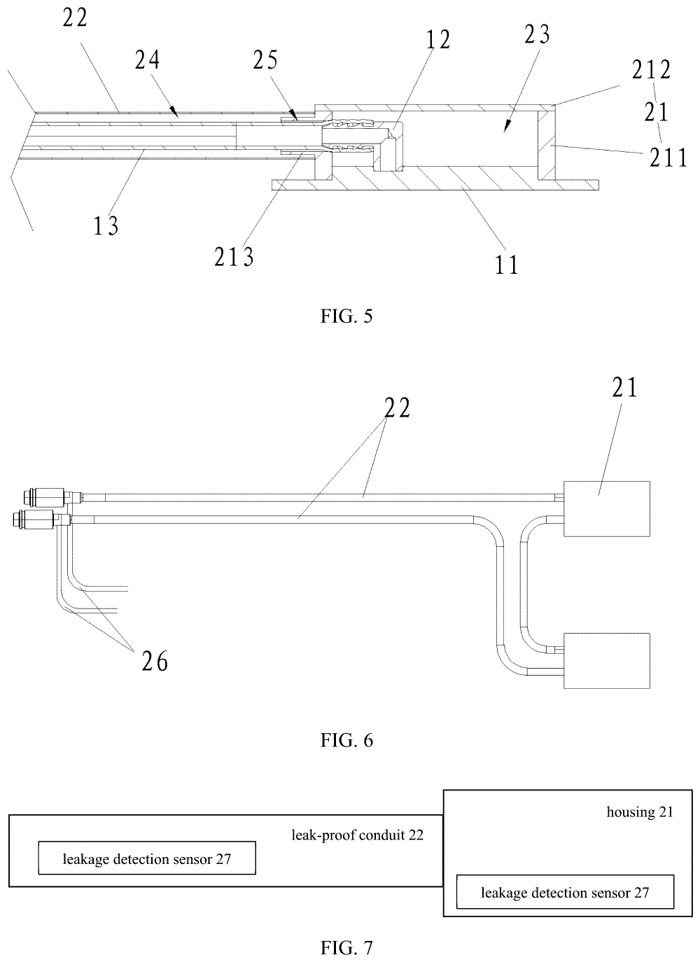

As shown in FIG. 1 to FIG. 7, an embodiment of the present application provides a detecting mechanism comprising a housing 21 and a leak-proof conduit 22. The housing 21 is used to cover a liquid cooling plate 11 of a liquid cooling device to be detected. The leak-proof conduit 22 is used to be fitted on the outside of a coolant conduit 13 of the liquid cooling device to be detected. Either or each of the housing 21 and the leak-proof conduit 22 is provided with a leakage detection sensor 27, as shown in FIG. 7.

In the embodiment, the detecting mechanism is applied to a liquid cooling device for detecting whether there is a coolant leakage in the liquid cooling device. The liquid cooling device includes a liquid cooling plate 11 and a coolant conduit 13. The liquid cooling plate 11 is attached to a heating element, the liquid cooling plate 11 includes a substrate and a top plate, the substrate is connected to the top plate, and a coolant flow channel for coolant flow is formed between the substrate and the top plate. An interface 12 is provided on the liquid cooling plate 11 for communicating the exteriority with the coolant flow channel. One end of the coolant conduit 13 communicates with the interface 12, and the other end is connected to a coolant source, for reciprocatingly transporting the coolant between the coolant source and the coolant flow channel.

Optionally, the coolant can be cooling water, or other common coolants such as inorganic calcium chloride, organic methanol, ethanol, etc.

In the embodiment, the detecting mechanism comprises a housing 21 and a leak-proof conduit 22. The housing 21 is used to cover the liquid cooling plate 11, and the leak-proof conduit 22 is used to be fitted over the coolant conduit 13. During assembly, one end of the coolant conduit 13 is inserted into the leak-proof conduit 22 from the end of the leak-proof conduit 22 away from the housing 21, then passes through the leak-proof conduit 22 and extends into the housing 21 communicating with the liquid cooling plate 11. The coolant from the external coolant source can flow into the liquid cooling plate 11 via the coolant conduit 13 to cool the heating element.

In the embodiment, preferably, the leakage detection sensors 27 are disposed inside the housing 21 and inside the leak-proof conduit 22, and the leakage detection sensors 27 adopts sheet-like sensors. The leakage detection sensors 27 cover the entire inner wall of the housing 21 and the entire inner wall of the leak-proof conduit 22, so as to avoid missed detection.

In the embodiment, a leakage detection sensor 27 can be set only in the housing 21, or only in the leak-proof conduit 22, or leakage detection sensors 27 can be set in both the housing 21 and the leak-proof conduit 22. In order to avoid the problem of missed detection, the latter is preferred in this embodiment. In the embodiment of the detecting mechanism, the coolant conduit 13 and the liquid cooling plate 11 will have coolant flowing inside in use. By installing the leak-proof conduit 22 on the outside of the coolant conduit 13, when the coolant conduit 13 leaks, the coolant will enter the leak-proof conduit 22; and by covering the liquid cooling plate 11 with the housing 21, when the liquid cooling plate 11 leaks, the coolant will be temporarily stored in the protective chamber 23. By setting the housing 21 and the leak-proof conduit 22, the leaked coolant can be temporarily stored, preventing the leaked coolant from dripping onto the working components and causing damage to the working components.

Furthermore, a leakage detection sensor 27 is provided in the housing 21 and/or the leak-proof conduit 22 for detecting whether there is a leak of coolant. When the liquid cooling plate 11 leaks coolant, the leaked coolant will only be temporarily stored in the housing 21 under the action of the housing 21, and will not flow around, so that the leakage detection sensor 27 in the housing 21 can detect the leakage of coolant in time. When the coolant conduit 13 leaks coolant, the leaked coolant will only be temporarily stored in the leak-proof conduit 22 under the action of the leak-proof conduit 22, and will not flow around, so that the leakage detection sensor 27 in the leak-proof conduit 22 can detect the leakage of coolant in time. Compared with the prior art, as long as there is a coolant leakage, it will be detected by the leakage detection sensors 27, enhancing accuracy of the detection result. In the embodiment of the detecting mechanism, a first gap 24 is defined between the leak-proof conduit 22 and the coolant conduit 13, and the interior of the housing 21 communicates with the exteriority through the first gap 24.

In the embodiment, due to the housing 21, the leaked coolant will accumulate inside the housing 21. Long-term contact between the coolant and the liquid cooling plate 11, or long-term contact between the coolant and the housing 21 may corrode the liquid cooling plate 11 and the housing 21, affecting the service life of both.

Therefore, in this embodiment, when the coolant conduit 13 is assembled, the first gap 24 is defined between the outer wall of the coolant conduit 13 and the inner wall of the leak-proof conduit 22. Through the first gap 24, the leaked coolant inside the housing 21 can be discharged from the housing 21 through the first gap 24, avoiding the coolant from accumulating inside the housing 21 for a long time.

In the embodiment, both the coolant conduit 13 and the leak-proof conduit 22 are taken as circular pipes as an example. In order to define the first gap 24 between the leak-proof conduit 22 and the coolant conduit 13, it is necessary to satisfy the following condition that an outer diameter of the coolant conduit 13 is smaller than an inner diameter of the leak-proof conduit 22.

In the embodiment, the detecting mechanism includes a protective chamber 23 defined between the housing 21 and the liquid cooling plate 11, the protective chamber 23 communicates with the exteriority through the first gap 24, the liquid cooling plate 11 is provided with the interface 12 communicating the exteriority with the interior of the liquid cooling plate 11, the interface 12 is located in the protective chamber 23, and the coolant conduit 13 communicates with the interface 12.

In the embodiment, the coolant flow channel is defined inside the liquid cooling plate 11 for the circulation of the coolant. The coolant flow channel is an S-shaped channel, which is distributed throughout the entire liquid cooling plate 11 to improve the cooling effect of the liquid cooling plate 11. The interface 12 is provided on the liquid cooling plate 11 to communicate the exteriority with the coolant flow channel. The coolant conduit 13 communicates with the interface 12. Since the main leakage position of the coolant in the liquid cooling plate 11 is at the interface 12, the interface 12 needs to be located in the protective chamber 23 to prevent the leaked coolant from flowing onto heating elements.

The housing 21 and the liquid cooling plate 11 together enclose the protective chamber 23, and the protective chamber 23 is sealed. That is, the protective chamber 23 is not connected to the exteriority, which can prevent the coolant from leaking from the protective chamber 23 to the exteriority. During assembly, one end of the coolant conduit 13 is inserted into the leak-proof conduit 22 via the end of the leak-proof conduit 22 away from the housing 21, then passes through the leak-proof conduit 22 and the extends into the protective chamber 23. A port of the coolant conduit 13 inside the protective chamber 23 is connected to the interface 12, so the coolant in the external coolant source can flow into the liquid cooling plate 11 through the coolant conduit 13.

In the embodiment, as mentioned above, the liquid cooling plate 11 includes the substrate and the top plate. In use, the substrate is connected to a heating element, and the interface 12 is set on the top plate. Correspondingly, the housing 21 is also covered on the top plate, that is, the top plate and the housing 21 together enclose the protective chamber 23.

In the embodiment, preferably, the leak-proof conduit 22 is a flexible tube, which can adapt to the coolant conduit 13 with different bending forms.

In the embodiment, the housing 21 is a groove-shaped structure with an opening at one end. During assembly, the end with the opening is connected to the top plate.

The detecting mechanism provided in this disclosure connects the housing 21 to the liquid cooling plate 11 to form the protective chamber 23, and protects the interface 12 within the protective chamber 23. When a coolant leakage occurs at the interface 12, the coolant will be temporarily stored in the protective chamber 23, without affecting the heating element. Furthermore, due to the leak-proof conduit 22 surrounding the coolant conduit 13, and the first gap 24 defined between the leak-proof conduit 22 and the coolant conduit 13, the coolant leaked into the protective chamber 23 can also flow out of the protective chamber 23 through the first gap 24, which can avoid the coolant affecting the service life of the housing 21 and the heating element, the coolant conduit 13 and the liquid cooling plate 11 inside the housing 21. It can effectively prevent the heating element from being damaged due to leakage of the liquid cooling plate 11. Furthermore, after the liquid cooling plate 11 is equipped with the detecting mechanism, even if the liquid cooling plate 11 leaks, the leaked coolant will not be stored in the protective chamber 23, and there is no need to shut down an equipment using the heating element for processing, so that the equipment can achieve uninterrupted operation.

In the embodiment, the liquid cooling plate 11 can be applied in server scenarios such as CPU (Central Processing Unit), graphics card, etc.

In the embodiment, the interface 12 can be an elbow with a pagoda joint commonly available on the market, connected to a pagoda joint at the end of the coolant conduit 13.

Optionally, in the embodiment, material of the housing 21 can be any one of PBT (polybutylene terephthalate), PFA (perfluoroalkoxy ethylene-tetrafluoroethylene copolymer), PE (polyethylene), PP (polypropylene), PTFE (polytetrafluoroethylene), FEP (fluorinated ethylene propylene copolymer), and PEEK (polyetheretherketone).

In the embodiment, as shown in FIG. 7, when leakage detection sensors 27 are installed in both the leak-proof conduit 22 and the housing 21, a “double insurance” detection can be realized.

For ease of description, the leakage detection sensor 27 inside the housing 21 is called a first leakage detection sensor, and the leakage detection sensor 27 inside the leak-proof conduit 22 is called a second leakage detection sensor.

Specifically, assume that the first leakage detection sensor fails. In this case, if the coolant leaks inside the protective chamber 23, the first leakage detection sensor cannot timely remind technicians of the coolant leakage inside the protective chamber 23. However, under the action of the first gap 24 and the second leakage detection sensor, when the coolant flows to the second leakage detection sensor, the second leakage detection sensor detects a liquid flow in the leak-proof conduit 22, and can still timely remind the technicians to discover the coolant leakage of the liquid cooling plate 11, convenient for dealing with it in time.

Besides, by cooperating with the first leakage detection sensor, the second leakage detection sensor can also remind technicians whether blockage occurs in the leakage-proof conduit 22.

The detecting mechanism provided in the embodiment, as shown in FIG. 1 to FIG. 5, comprises a through-hole 210 defined on a side wall of the housing 21. The coolant conduit 13 extends through the through-hole 210 into the housing 21 and communicates with the liquid cooling plate 11. A second gap 25 is defined between the coolant conduit 13 and the through-hole 210. The leak-proof conduit 22 is connected to an external surface of the through-hole 210, and the first gap 24 communicates with the interior of the housing 21 through the second gap 25.

In the embodiment, the through-hole 210 is provided on the side wall of the housing 21, and the coolant conduit 13 can extend into the housing 21 through the through-hole 210, specifically extending into the protective chamber 23. Furthermore, an inner diameter of the through-hole 210 is larger than the outer diameter of the coolant conduit 13, so that the second gap 25 can be defined between the coolant conduit 13 and the through-hole 210. The first gap 24 between the leak-proof conduit 22 and the coolant conduit 13 is connected to the protective chamber 23 through the second gap 25 between the through-hole 210 and the leak-proof conduit 22.

Optionally, an internal surface of the leak-proof conduit 22 is connected to the external surface of the through-hole 210 to avoid the second gap 25 being too small when the leak-proof conduit 22 is inserted into the through-hole 210, affecting the discharge of the coolant through the second gap 25.

In the embodiment, the through-hole 210 communicates with the leak-proof conduit 22, which has a simple structure and is easy to manufacture.

Optionally, a structure such as a notch can be provided on the housing 21 to allow the coolant conduit 13 to extend into the housing 21 and to allow the first gap 24 to communicate with the protective chamber 23.

Furthermore, in the embodiment, in order to facilitate the connection between the housing 21 and the leak-proof conduit 22, a connecting portion 213 is provided on the housing 21, which is specifically used for connecting to the leak-proof conduit 22. The connecting portion 213 corresponds to the through-hole 210, that is, the connecting portion 213 is provided at each through-hole 210. A passage 214 is provided on the connecting portion 213, and the passage 214 communicates with the through-hole 210, that is, the passage 214 communicates with both the inside and outside of the housing 21. The connecting portion 213 is connected to the leak-proof conduit 22. Optionally, the connecting portion 213 and the leak-proof conduit 22 may be connected by a snap connection, a plug connection, a threaded connection, or the like.

In the embodiment, after the leak-proof conduit 22 is assembled with the connecting portion 213, the coolant conduit 13 passes through the passage 214 and extends into the housing 21, specifically into the protective chamber 23. Of these, the second gap 25 has two sections, one between the through-hole 210 and the coolant conduit 13, and the other between the outer wall of the coolant conduit 13 and the inner wall of the passage 214. The first gap 24 communicates with the protective chamber 23 through the second gap 25.

That is, when the detecting mechanism is assembled, the leak-proof conduit 22, the passage 214, the through-hole 210, and the interior of the housing 21 are connected in sequence.

When assembling the coolant conduit 13, the end of the coolant conduit 13 passes through the leakproof conduit 22, the passage 214, and the through-hole 210 in sequence, and then extends into the housing 21.

In the embodiment, the end of the leak-proof conduit 22 away from the hosing 21 is lower, and the end closer to the housing 21 is higher, which facilitates the discharge of the leaked coolant from the protective chamber 23.

For example, structures such as the through-holes 210 are defined on the side wall of the housing 21 facing the ground, and once the side wall is set horizontally, the leak-proof conduit 22 will be set vertically afterwards.

Furthermore, structures such as drainage slopes for guiding the coolant to the through-holes 210 can be set in the housing 21, which promotes drainage of the leaked coolant.

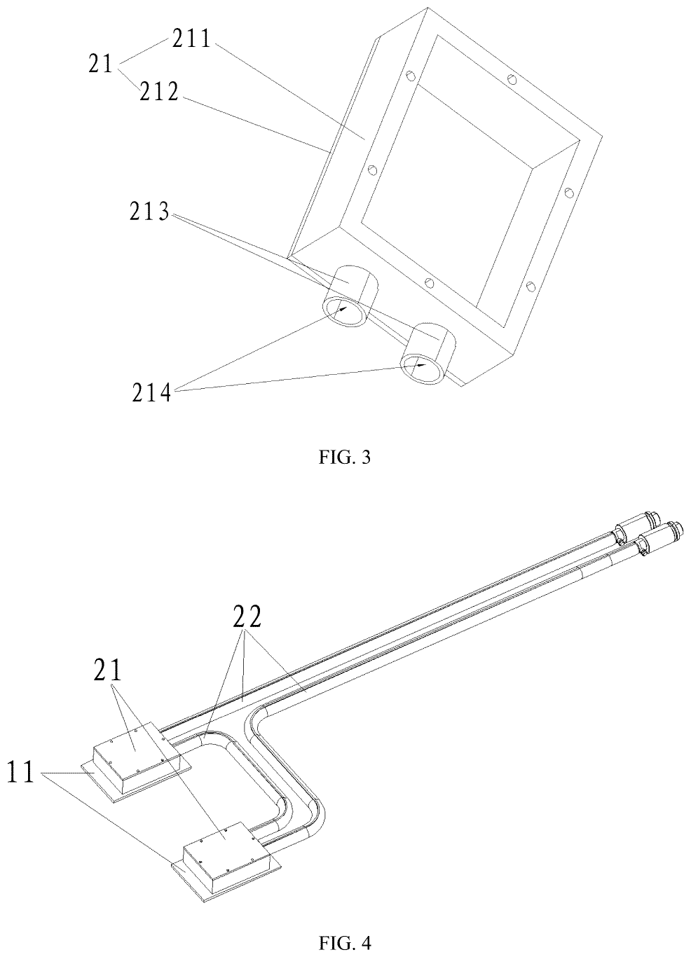

Optionally, as shown in FIG. 3, the connecting portion 213 is a cylindrical joint, which is inserted into the leak-proof conduit 22.

In the embodiment, the connecting portion 213 is a cylindrical joint corresponding to the leak-proof conduit 22, and the leak-proof conduit 22 and the cylindrical joint are connected by insertion, specifically, the cylindrical joint is inserted into the leak-proof conduit 22.

In the embodiment, the connecting portion 213 is set as a cylindrical joint, which, compared to square, elliptical, and other structures, can facilitate the assembly of the leak-proof conduit 22 and the connecting portion 213. Moreover, the cylindrical joint is easy to process, and is often a standard part with a low cost.

In the embodiment of the detecting mechanism, the leak-proof conduit 22 and the connecting portion 213 are sealed, to ensure that the coolant does not leak from the connection between the leak-proof conduit 22 and the connecting portion 213 when the coolant in the protective chamber 23 is transported outwards.

Optionally, the leak-proof conduit 22 can be a common flexible tube, which can be sealed by a structure such as a sealing ring or sealant at the connection.

Optionally, the leak-proof conduit 22 can also be a heat shrink tube. After inserting the connecting portion 213 into the leak-proof conduit 22, connection strength between the leak-proof conduit 22 and the connecting portion 213 can be enhanced by heating, and sealing can also be achieved.

By sealing the leak-proof conduit 22 and the connecting portion 213, it is possible to prevent the leaked coolant of the protective chamber 23 from leaking between the leak-proof conduit 22 and the connecting portion 213, so that the leaked coolant of the protective chamber 23 can only flow to subsequent recycling components.

The detecting mechanism according to the embodiment, as shown in FIG. 1 to FIG. 5, comprises the housing 21 including a frame 211 and a cover plate 212. One end of the frame 211 is connected to the cover plate 212, and the other end is connected to the liquid cooling plate 11. When the housing 21 is fitted onto the liquid cooling plate 11, the liquid cooling plate 11, the frame 211, and the cover plate 212 jointly enclose the protective chamber 23.

In the embodiment, the housing 21 is divided into two parts, the frame 211 and the cover plate 212. The frame 211 can be a square frame or a circular frame, and the specific shape can vary according to the actual situation.

In the embodiment, one end of the frame 211 is connected to the cover plate 212, forming the groove-shaped structure, and the other end of the frame 211 is connected to the top plate of the liquid cooling plate 11. The top plate of the liquid cooling plate 11, the frame 211 of the housing 21, and the cover plate 212 of the housing 21 jointly enclose the protective chamber 23.

In the embodiment, the housing 21 is composed of two parts: the frame 211 and the cover plate 212. The structure is simple, easy to manufacture, and low in cost. Moreover, the size of the frame 211 can be set according to the size of the liquid cooling plate 11, making the connection between the housing 21 and the liquid cooling plate 11 more stable.

In the embodiment of the detecting mechanism, optionally, the frame 211 and the cover plate 212 are integrated, and the frame 211 and the liquid cooling plate 11 are sealed therebetween.

In the embodiment, the frame 211 and the cover plate 212 can be an integral structure, i.e., integrally molded with the housing 21, which has a higher manufacturing efficiency, and at the same time, the frame 211 and the cover plate 212 are sealed through integral molding.

In this embodiment, in order to improve the sealing of the protective chamber 23, a sealing structure is provided between the frame 211 and the liquid cooling plate 11, specifically, between the frame 211 and the top plate. The sealing structure can be a sealing ring provided between the frame 211 and the top plate, or a sealant.

In the embodiment, the frame 211 is connected to the top plate via bolts, which also secure the sealing ring, enhancing the airtightness of the protective chamber 23.

In the embodiment of the detecting mechanism, optionally, the frame 211 and the cover plate 212 are separate structures, and the frame 211 and the cover plate 212 are sealed therebetween, as well as the frame 211 and the liquid cooling plate 11 are sealed therebetween.

In the embodiment, the frame 211 and the cover 212 are separate structures, which can be connected by structures such as bolts. When the frame 211 or the cover 212 is damaged, one of them can be replaced separately, which is convenient for technicians to maintain and repair.

In this embodiment, to improve the sealing of the protective chamber 23, the frame 211 and the cover plate 212, as well as the frame 211 and the top plate, are all sealed therebetween. Optionally, a sealing ring or the like can be provided between the frame 211 and the cover plate 212, and between the frame 211 and the top plate, or a sealant can be applied.

In the embodiment, the frame 211 is connected to the top plate by bolts, and the frame 211 is connected to the cover plate 212 by bolts.

The embodiment of the detecting mechanism, as shown in FIG. 6, also includes a recycling component. The leak-proof conduit 22 is connected to a diversion conduit 26 at the end away from the housing 21, and the first gap 24 communicates with the recycling component through the diversion conduit 26.

In the embodiment, a branch is also branched off from the end of the leak-proof conduit 22 away from the housing 21, and the branch is the diversion conduit 26. The diversion conduit 26 communicates with the leak-proof conduit 22. When the coolant conduit13 is inserted into the leak-proof conduit 22, the first gap 24 is defined between the leak-proof conduit 22 and the coolant conduit 13, and the first gap 24 communicates with the diversion conduit 26.

In the embodiment, the recycling component can be a recovery bin or a waste liquid pool, etc., which is used to recover the leaked coolant. The leak-proof conduit 22 communicates with the recycling component through the diversion conduit 26, and the coolant leaked to the protective chamber 23 and/or the first gap 24 flows into the recycling component through the diversion conduit 26, so as to avoid the leaked coolant from harming external devices or the environment, and reduce losses.

In the embodiment of the detecting mechanism, the liquid cooling plate 11 typically has two interfaces 12. Correspondingly, the detecting mechanism includes two leak-proof conduits 22, and two connection portions 213 are set on the housing 21.

In the embodiment, when the liquid cooling plate 11 is in use, there may be multiple liquid cooling plates 11 connected in series. Taking two liquid cooling plates 11 as an example, the two liquid cooling plates 11 have three coolant conduits 13, one of which serves as an inlet conduit and is connected to the interface 12 on one of the liquid cooling plates 11, another serves as an outlet conduit and is connected to the interface 12 on the other liquid cooling plate 11, and the remaining coolant conduit 13 is connected to the remaining interfaces 12 on the two liquid cooling plates 11 at both ends.

Correspondingly, the detecting mechanism comprises two housings 21 and three leak-proof conduits 22, the three leak-proof conduits 22 corresponding to the three coolant conduits 13, the two housings 21 being respectively covered on the two liquid cooling plates 11, and the three leak-proof conduits 22 being respectively sleeved on the corresponding coolant conduits 13.

Furthermore, since the housing 21 is located at the lowest position when the liquid cooling device is installed onto the server, the leaked coolant will accumulate in the housing 21 in case of leakage. Therefore, the leakage detection sensor 27 is arranged inside the housing 21.

For dual-path servers, consisting of two liquid cooling plates 11 connected in series between three conduits, the leakage detection sensor 27 in the housing 21 is connected in series or parallel with signal transmission cables placed between leak-proof conduits 22 and the coolant conduit 13. When the signal transmission cables are installed, the electrodes enter the housing 21 from the gap between an inner wall of a step hole and the coolant conduit 13. When a leakage occurs, the leakage is detected and an alarm is triggered.

Therefore, when a leakage occurs in the coolant conduit 13 of the liquid cooling plate 11, the leakage detection sensor 27 will quickly identify and alert, while the leaked coolant will be blocked by the two-level leak-proof structure and diverted to the exteriority of a server. The leaked coolant can be guided to the recycling component through the coolant conduit 13 in the server for leakage recovery, to avoid harming external devices or the environment and reduce losses. At the same time, the server can continue to operate without shutdown in a short period of time, ensuring data safety.

The foregoing is only a preferred embodiment of the present invention, and is not intended to limit the present invention, which is subject to various changes and variations for those skilled in the art. Any modification, equivalent replacement, improvement, etc. made within the spirit and principles of the present invention shall be included in the scope of protection of the present invention.

1. A detecting mechanism, comprising: a housing and a leak-proof conduit; wherein the housing is used to cover a liquid cooling plate of a liquid cooling device to be detected; the leak-proof conduit is used to be fitted over a coolant conduit of the liquid cooling device to be detected, and either or each of the housing and the leak-proof conduit is provided with a leakage detection sensor.

2. The detecting mechanism according to claim 1, wherein a first gap is defined between the leak-proof conduit and the coolant conduit, and the housing communicates with the exteriority through the first gap.

3. The detecting mechanism according to claim 2, wherein a protective chamber is defined between the housing and the liquid cooling plate, the protective chamber communicates with the exteriority through the first gap; the liquid cooling plate is provided with an interface communicating the exteriority with the liquid cooling plate, the interface is located in the protective chamber, and the coolant conduit is connected to the interface.

4. The detecting mechanism according to claim 2, wherein a side wall of the housing is provided with a through-hole; the coolant conduit passes through the through-hole, extends into the housing and communicates with the liquid cooling plate; a second gap is defined between the coolant conduit and the through-hole; the leak-proof conduit is connected to the external surface of the through-hole, and the first gap communicates with the housing through the second gap.

5. The detecting mechanism according to claim 4, wherein an outer wall of the housing is provided with a connecting portion, the connecting portion is disposed corresponding to the through-hole, the connecting portion is provided with a passage communicating with the through-hole; the leak-proof conduit is connected to the connecting portion, the coolant conduit passes through the passage and the through-hole to extend into the housing; a second gap is defined between the coolant conduit and the through-hole, and the first gap communicates with the housing through the second gap.

6. The detecting mechanism according to claim 5, wherein the connecting portion is a cylindrical joint, and the cylindrical joint is inserted into the leak-proof conduit.

7. The detecting mechanism, according to claim 5, wherein the leak-proof conduit and the connecting portion are sealed therebetween.

8. The detecting mechanism according to claim 3, wherein the housing comprises a frame and a cover; one end of the frame is connected to the cover plate, and the other end is connected to the liquid cooling plate; and the liquid cooling plate, the frame, and the cover plate jointly enclose the protective chamber, when the housing is fitted onto the liquid cooling plate.

9. The detecting mechanism according to claim 8, wherein the frame and the cover plate are sealed therebetween, and the frame and the liquid cooling plate are sealed therebetween.

10. The detecting mechanism according to claim 2, comprising a recycling component, wherein the recycling component is used for recycling the coolant; the leak-proof conduit communicates with a diversion conduit at an end away from the housing, and the first gap communicates with the recycling component through the diversion conduit.

11. A detecting mechanism, comprising: a housing and a leak-proof conduit; the housing is used to cover a liquid cooling plate of a liquid cooling device to be detected; the leak-proof conduit is used to cover a coolant conduit of the liquid cooling device to be detected; wherein a first leakage detection sensor is provided the housing, and a second leakage detection sensor is provided in the leak-proof conduit.

12. The detecting mechanism according to claim 11, wherein the housing and the liquid cooling plate enclose a sealed protective chamber, the leak-proof conduit and the coolant conduit defines a first gap, and the protective chamber communicates with the exteriority through the first gap.

13. The detecting mechanism according to claim 12, wherein a side wall of the housing defines a through-hole for the coolant conduit to extend into the housing, a second gap is defined between the through-hole and the coolant conduit; the leak-proof conduit is connected to an external surface of the through-hole, and the first gap communicates with the protective chamber through the second gap.

14. The detecting mechanism according to claim 13, wherein an inner diameter of the through-hole is larger than an outer diameter of the coolant conduit, and the internal surface of the leak-proof conduit is connected to the external surface of the through-hole.

15. The detecting mechanism according to claim 13, wherein a connecting portion is provided at the through-hole, the connecting portion is provided with a passage communicating with the through-hole, and the connecting portion is connected to the leak-proof conduit.

16. The detecting mechanism according to claim 14, wherein the leak-proof conduit is a flexible tube, and the leak-proof conduit is provided with a sealing structure at a connection with the connecting portion;
or, the leak-proof conduit is a heat shrink tube, and the connecting portion is inserted into the leak-proof conduit and connected to the leak-proof conduit by heating.

17. The detecting mechanism according to claim 14, wherein the housing is a groove-shaped structure and an end with an opening is connected to a top plate of the liquid cooling plate, the housing includes a frame and a cover plate;
the frame and cover plate are integrated, a sealing structure is provided between the frame and the top plate of the liquid cooling plate, and the frame is connected to the top plate by bolts;
or, the frame and the cover plate are separate structures, a sealing structure is provided between the frame and the cover plate, a sealing structure is provided between the frame and the top plate, the frame and the cover plate are connected by bolts, and the frame and the top plate are connected by bolts.

18. The detecting mechanism according to claim 12, wherein the leak-proof conduit branches off at an end away from the housing to form a diversion conduit, and the first gap communicates with the recycling component through the diversion conduit.

19. The detecting mechanism according to claim 12, wherein the protective chamber receives an interface on the liquid cooling plate connected to a coolant conduit.

20. The detecting mechanism according to claim 11, wherein one end of the leak-proof conduit away from the housing is lower than the other end of the leak-proof conduit closer to the housing.
